(19) United States
(12) Patent Application Publication
(10) Pub. No.: US 2016/0231372 A1
(43) Pub. Date: Aug. 11, 2016

(54) Wire Diagram Tagging System

(71) Applicant: Ivani, LLC, Dardenne Prairie, MO (US)

(72) Inventors: Matthew Wootton, O'Fallon, MO (US); Christopher Nissman, Tucson, AZ (US); Justin McKinney, Wildwood, MO (US); Elizabeth Mahon, Fort Collins, CO (US); Matthew Wismer, Malvern, PA (US); Claire Barnes, Ben Lomond, CA (US); James Wu, Great Falls, VA (US); Nathan Lintz, Needham, MA (US); Caitlin Riley, San Diego, CA (US)

(21) Appl. No.: 14/824,994

(22) Filed: Aug. 12, 2015

Related U.S. Application Data
(60) Provisional application No. 62/113,123, filed on Feb. 6, 2015.

(51) Int. Cl. G01R 31/02

(52) U.S. Cl. CPC G01R 31/021

(57) ABSTRACT

Systems and methods for creating a data representation of the structure of an electrical system or network. Wireless tags, such as RFID tags, near field communication tags, and other short-range wireless communication technologies, are used to uniquely identify discrete components of the electrical network, and user-provided metadata is associated with each tag, generally using a software application on a smart device which is in communication with the tags. Metadata necessarily includes the links between tags. The smart device communicates with a data server to create, update, and retrieve the user-supplied data to and from a remote storage system.

### CROSS REFERENCE TO RELATED APPLICATIONS

This application claims benefit of U.S. Provisional Patent Application Ser. No. 62/113,123, filed Feb. 6, 2015, the entire disclosure of which is herein incorporated by reference.

### BACKGROUND

1. Field of the Invention

This disclosure relates to the field of electrical wiring, and specifically to systems and methods for locating electrical wiring in walls.

2. Description of the Related Art

Electricians have long been installing wires into buildings based upon drawings or schematics, but they often modify the installation based upon conditions at the job site. Later, when the installation needs to be modified or repaired, the new electricians working on the installation would benefit from access to up-to-date drawings, but they are rarely available. This is often because the original electricians were unwilling to put the time into creating “as-built” drawings unless paid for, but budget-conscious customers generally trim such projects from work orders. This means wiring drawings are rarely up to date. Furthermore, even the out-of-date schematics are rarely provided to building owners and are not otherwise publicly available, meaning that future electricians working on the installation start with virtually no knowledge of the electrical system. This results in wasted time and money as they investigate the environment to learn basic information that could be easily provided in an up-to-date schematic. Making the process of documenting and updating the electrical environment simple and accessible would provide for better electrical troubleshooting and problem-solving capabilities.

This is typically addressed using meters and sensors which can detect current through the wall. However, these techniques lack precision and specificity, as they generally rely on detecting the presence of current, rather than of specific electrical hardware.

### SUMMARY

The following is a summary of the invention in order to provide a basic understanding of some aspects of the invention. This summary is not intended to identify key or critical elements of the invention or to delineate the scope of the invention. The sole purpose of this section is to present some concepts of the invention in a simplified form as a prelude to the more detailed description that is presented later.

Because of these and other problems in the art, described herein, among other things, is a method for collecting and storing electrical wiring diagram data comprising: providing a plurality of electrical components installed in an electrical system; for each electrical component in the plurality of electrical components: associating with the each electrical component a tag having a memory containing a unique identifier for the tag; receiving the unique identifier by a smart device; entering, using the smart device, metadata describing the each electrical component; transmitting, using the smart device, to a data server the unique identifier and at least some of the entered metadata; storing in a non-volatile computer-readable storage medium a dataset for the each electrical component, the created dataset comprising an indication of the transmitted unique identifier, and the indication being associated in the created dataset with an indication of at least of some at least some of the transmitted entered metadata.

In an embodiment, for at least one of the each electrical components, the associating step comprises physically placing the tag proximate to the each electrical component.

In another embodiment, for at least one of the each electrical components, the associating step comprises placing the tag in physical contact with the each electrical component.

In a still further embodiment, for at least one of the each electrical components, the tag is physically integrated into the each electrical component.

In a still further embodiment, the method further comprises: for a first electrical component in the plurality of electrical components, the entering step further comprises indicating to the smart device that the first electrical component is a parent electrical component; for a second electrical component in the plurality of electrical components, the entering step further comprises indicating to the smart device that the second electrical component is a child electrical component of the first electrical component; associating, in the non-volatile computer-readable storage medium, the created dataset for the second electrical component with the created dataset for the first electrical component.

In a still further embodiment, the association of the second electrical component dataset with the first electrical component dataset is a parent/child relationship. It will be understood by one of ordinary skill in the art that the program logic is programmed to identify other types of relationships between two or more nodes based on one or more parent/child relationships. By way of example and not limitation, where Node A is a parent of Node B, and Node B is a parent of Node C, the program logic understands that Node A is a grandparent of Node C by implication. Likewise, the program logic can identify other relationships among nodes to identify families of related needs, such as “siblings” under a common parent or “cousins” under a common grandparent.

In a still further embodiment, the method further comprises: in response to a user request, for at least one electrical component in the plurality of electrical components, retrieving from the non-volatile computer-readable storage medium the created dataset for the at least one electrical component; based upon the at least one retrieved datasets for the plurality of electrical components, generating a schematic diagram of the electrical system; displaying the generated schematic diagram to a user.

In a still further embodiment, the method further comprises: for at least one electrical component in the plurality of electrical components, retrieving the identifier from tag associated with the at least one electrical component; requesting the created dataset for the at least one electrical component, the requesting comprising transmitting the retrieved identifier for the associated tag; receiving from the non-volatile computer-readable storage medium a copy of the created dataset for the at least one electrical component; displaying a visualization of the received created dataset for the at least one electrical component.

In a still further embodiment, the method further comprises the displaying a visualization of the received created dataset for the at least one electrical component comprises displaying at least some of the indicated metadata associated in the dataset with the unique identifier; editing the displayed at least some of the indicated metadata; transmitting to the data server the unique identifier and the edited metadata; updating in the non-volatile computer-readable storage medium the dataset for the at least one electrical component, the updating comprising altering the indication of at least of some of at least some of the transmitted entered metadata to conform to the transmitted edited metadata.

In a still further embodiment, the displayed visualization is displayed on the smart device.

In a still further embodiment, the displayed visualization is displayed on a second smart device.

In a still further embodiment, the displayed visualization includes a representation of the collected data over time.

In a still further embodiment, for at least one of the electrical components in the plurality of electrical components, the associated tag is a passive tag.

In a still further embodiment, the at least one passive tag is integrated into a wire component of the electrical system.

In a still further embodiment, for at least one of the electrical components in the plurality of electrical components, the associated tag is an active tag.

In a still further embodiment, the method further comprises collecting, by the at least one active tag, data indicative of a condition of the electrical system.

In a still further embodiment, the condition of the electrical system is selected from the group consisting of: current; voltage; temperature; humidity; carbon dioxide levels; and, carbon monoxide levels.

In a still further embodiment, the metadata includes data indicative of the voltage and current carrying capacity of a segment of the electrical system.

In a still further embodiment, at least one electrical component in the plurality of electrical components is selected from the group consisting of: wires; connectors; receptacles; switches; fuses; and, circuit breakers.

### BRIEF DESCRIPTION OF THE DRAWINGS

FIG. 1 depicts a schematic diagram of a system for creating a data representation of the layout of an electrical system.

FIG. 2 depicts a more detailed schematic diagram of such a system.

FIG. 3 depicts a flow chart showing an embodiment of method for creating a data representation of the layout of an electrical system.

FIGS. 4A, 4B, and 4C depict an embodiment of a method for tagging electrical components.

FIGS. 5A, 5B, 5C, 5D, 5E, and 5F depict an illustrative example of a method for tagging an electrical system.

### DESCRIPTION OF THE PREFERRED EMBODIMENT(S)

The following detailed description and disclosure illustrates by way of example and not by way of limitation. This description will clearly enable one skilled in the art to make and use the disclosed systems and methods, and describes several embodiments, adaptations, variations, alternatives and uses of the disclosed systems and methods. As various changes could be made in the above constructions without departing from the scope of the disclosures, it is intended that all matter contained in the description or shown in the accompanying drawings shall be interpreted as illustrative and not in a limiting sense.

Throughout this disclosure, the term “computer” describes hardware which generally implements functionality provided by digital computing technology, particularly computing functionality associated with microprocessors. The term “computer” is not intended to be limited to any specific type of computing device, but it is intended to be inclusive of all computational devices including, but not limited to: processing devices, microprocessors, personal computers, desktop computers, laptop computers, workstations, terminals, servers, clients, portable computers, handheld computers, smart phones, tablet computers, mobile devices, server farms, hardware appliances, minicomputers, mainframe computers, video game consoles, handheld video game products, and wearable computing devices including but not limited to eyewear, wristwear, pendants, and clip-on devices.

As used herein, a “computer” is necessarily an abstraction of the functionality provided by a single computer device outfitted with the hardware and accessories typical of computers in a particular role. By way of example and not limitation, the term “computer” in reference to a laptop computer would be understood by one of ordinary skill in the art to include the functionality provided by pointer-based input devices, such as a mouse or track pad, whereas the term “computer” used in reference to an enterprise-class server would be understood by one of ordinary skill in the art to include the functionality provided by redundant systems, such as RAID drives and dual power supplies.

It is also well known to those of ordinary skill in the art that the functionality of a single computer may be distributed across a number of individual machines. This distribution may be functional, as where specific machines perform specific tasks; or, balanced, as where each machine is capable of performing most or all functions of any other machine and is assigned tasks based on its available resources at a point in time. Thus, the term “computer” as used herein, can refer to a single, standalone, self-contained device or to a plurality of machines working together or independently, including without limitation: a network server farm, cloud computing system, software-as-a-service, or other distributed or collaborative computer networks.

Those of ordinary skill in the art also appreciate that some devices which are not conventionally thought of as “computers” nevertheless exhibit the characteristics of a “computer” in certain contexts. Where such a device is performing the functions of a “computer” as described herein, the term “computer” includes such devices to that extent. Devices of this type include but are not limited to: network hardware, print servers, file servers, NAS and SAN, load balancers, and any other hardware capable of interacting with the systems and methods described herein in the matter of a conventional “computer.”

Throughout this disclosure, the term “software” refers to code objects, program logic, command structures, data structures and definitions, source code, executable and/or binary files, machine code, object code, compiled libraries, implementations, algorithms, libraries, or any instruction or set of instructions capable of being executed by a computer processor, or capable of being converted into a form capable of being executed by a computer processor, including without limitation virtual processors, or by the use of run-time environments, virtual machines, and/or interpreters. Those of ordinary skill in the art recognize that software can be wired or embedded into hardware, including without limitation onto a microchip, and still be considered “software” within the meaning of this disclosure. For purposes of this disclosure, software includes without limitation: instructions stored or storable in RAM, ROM, flash memory BIOS, CMOS, mother and daughter board circuitry, hardware controllers, USB controllers or hosts, peripheral devices and controllers, video cards, audio controllers, network cards, Bluetooth® and other wireless communication devices, virtual memory, storage devices and associated controllers, firmware, and device drivers. The systems and methods described here are contemplated to use computers and computer software typically stored in a computer- or machine-readable storage medium or memory.

Throughout this disclosure, terms used herein to describe or reference media holding software, including without limitation terms such as “media,” “storage media,” and “memory,” may include or exclude transitory media such as signals and carrier waves.

Throughout this disclosure, the terms “web,” “web site,” “web server,” “web client,” and “web browser” refer generally to computers programmed to communicate over a network using the HyperText Transfer Protocol (“HTTP”), and/or similar and/or related protocols including but not limited to HTTP Secure (“HTTPS”) and Secure Hypertext Transfer Protocol (“SHTP”). A “web server” is a computer receiving and responding to HTTP requests, and a “web client” is a computer having a user agent sending and receiving responses to HTTP requests. The user agent is generally web browser software.

Throughout this disclosure, the term “network” generally refers to a voice, data, or other telecommunications network over which computers communicate with each other. The term “server” generally refers to a computer providing a service over a network, and a “client” generally refers to a computer accessing or using a service provided by a server over a network. Those having ordinary skill in the art will appreciate that the terms “server” and “client” may refer to hardware, software, and/or a combination of hardware and software, depending on context. Those having ordinary skill in the art will further appreciate that the terms “server” and “client” may refer to endpoints of a network communication or network connection, including but not necessarily limited to a network socket connection. Those having ordinary skill in the art will further appreciate that a “server” may comprise a plurality of software and/or hardware servers delivering a service or set of services. Those having ordinary skill in the art will further appreciate that the term “host” may, in noun form, refer to an endpoint of a network communication or network (e.g., “a remote host”), or may, in verb form, refer to a server providing a service over a network (“hosts a website”), or an access point for a service over a network.

Throughout this disclosure, terms such as “electric component,” “electrical component,” and “electric element” generally refer to discrete physical devices or entities used in electrical circuits, systems, or networks, which generally affect electrons or their fields in such systems, or which contain or organize such components, including, without limitation, electronic components or elements. For illustrative purposes, such components or elements include, without limitation: power sources, including without limitation batteries, external circuits, and alternative energy sources such as solar panels and wind turbines; resistors; capacitors; inductors; timers and timing circuits; sensors; transistors; fuses; wires and cables; switches; electrical illumination sources such as light bulb and lamp fixtures; controllers and control knobs; junction boxes; current sensors; logic circuits and/or gates; conduit; dimmers; power receptacles; circuit breakers; safety devices, including but not necessarily limited to smoke and fire alarms and security and surveillance systems; automation components; meters; grounds; load centers; and, other systems and devices which now or in the future are commonly hard wired into electrical networks (as opposed to plugged into a wall receptacle).

This disclosure generally describes, among other things, systems and methods for an electrical wiring diagram tagging system. The system may use one or both of passive and active tags to collect data about the electrical system and/or its components. Such data is generally collected using a mobile device or handheld device (generally referred to herein as “smart device”), which provides apparatus or means for transmitting and/or loading such data into digital storage, including remote digital storage (e.g., cloud storage), and for presenting information in a user-friendly format.

The system and methods generally comprise creating and updating a database of information about an electrical installation environment using automatic and/or manual processes. The database can then be used to generate schematics and other reporting ad hoc. Generally, the systems and methods provide an accessible electronic record of the installation, and may also provide contact information about the original installer and prior service electricians, allowing a building owner to access “as-built” schematics if and as necessary.

Further, certain embodiments of the systems and methods collect data from the electrical system related to aspects such as electrical usage in a facility and/or the general state of the electrical system. Such data can be analyzed and processed to produce actionable analytics, which in turn can be used to alter or modify the physical layout of the system, or alter power management policies or procedures to reduce costs and/or increase usage efficiency.

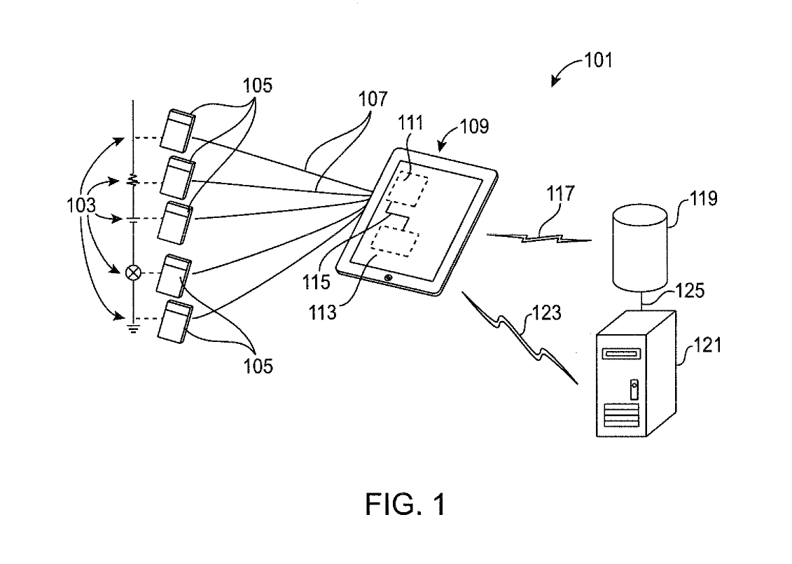

FIG. 1 depicts an exemplary embodiment, at a high level, of a system and method for tagging elements of an electrical circuit using active and/or passive tags. In the depicted embodiment (101), one or more electrical components (103) have an associated tag (105). Each one of those tags (105) communicates (107) with a smart device (109). The smart device (109) in turn communicates (117) with a storage system (119). Alternatively, the smart device (109) may communicate (123) with a computer server system (121), which in turn communicates (125) with the storage system (119). The smart device (109) generally includes a transmitter/receiver system (111) operatively coupled (115) to a microprocessor (113) by circuitry.

In the depicted embodiment of FIG. 1, tags (105) are associated with an electrical component (103) and generally contain a non-transitory data storage or data storage means, such as but not limited to a solid state memory system. This data storage may include a unique identifier for the tag (105), or may be programmable to include a unique identifier for the tag (105). The tags (105) generally are data generating elements, which either actively or passively collect and transmit data, generally wirelessly. This may be done in an embodiment using a scanner or scanning means, such as a handheld scanner communicatively and/or operatively coupled to a smart device (109), or a smart device (109) having an integrated scanner or scanning means.

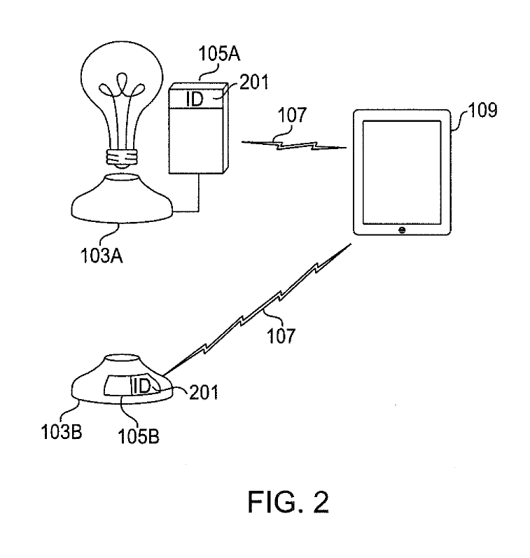

Tags (105) may be associated with electrical components (103) in a number of ways. At the most basic level, a tag (105) may simply be placed or stored physically proximate to a component (103) and associated with the component (103) in data as described elsewhere herein. Alternatively, as depicted in FIG. 2, the tag (105A) may be physically coupled with the component (103A). Third, and preferably, an electrical component (103B) may include a tag (105B) or equivalent circuitry and/or functionality as an integrated element (105B) of such component (103B).

The depicted smart device (109) generally comprises a handheld device such as a tablet computer, smart phone, wearable technology, or other portable computer technology having the common features of such devices. Those features include, but are not necessarily limited to, a display, a microprocessor, various transmitter/receivers, one or more input systems (such as voice interface systems, voice activated digital assistants, keypads, touchscreens, and so forth). The smart device (109) generally serves as a data collection element. By way of example and not limitation, tags (105) may be scanned (107), accessed (107), or tag data otherwise received (107) by the smart device (109), and the received or scanned data is transmitted (117) and (123) by the smart device (109) to a data storage system (119).

The smart device (109) is generally used for scanning and information display, and generally comprises the appropriate transceivers (111), which can request (107) data from the tags (105) and read their (105) response (107). The smart device (109) generally further comprises a processor (113) operatively and/or communicatively coupled (115) to other components, such as the transceiver (111). The smart device (109) generally also comprises a data storage for storing software, including application software, for execution by the processor (113). The smart device (109) may initiate the read (107) and process the response (107). The smart device (109) will generally further comprise a display or display means, which may be used to display information and provide interface elements for data entry, such as a touchscreen or voice recognition software. The smart device (109) is generally communicatively coupled to the data storage (109), directly (117) or indirectly (123) through a computer server (121) system.

The smart device (109) is typically a smart phone but may be another device or a plurality of devices. By way of example and not limitation, the smart device (109) may be made up of a smaller set of connected devices which, as a collective, can complete the same job as the smart device (109). For example, the smart device (109) may be communicatively coupled to an external transceiver (not depicted), physically and/or wirelessly, and the external transceiver may communicate with one or more tags (105), such as over a different radio frequency or channel than the base smart device (109). Effectively, the remote transceiver, or a plurality of such remote transceivers, would be understood by one of ordinary skill in the art as being part of the smart device (109) as described herein and depicted in FIG. 1.

The depicted storage system (119) generally comprises a secure cloud storage system, though other storage systems are suitable for use with the systems and methods and may be substituted in an embodiment. The storage system (119) generally comprises a structured database system for storing information received by the smart device (109) from one or more tags (105), or generated by or inputted into the smart device (109). The data storage system (119) may comprise, or be accessed by, a data aggregator (not depicted), which aggregates the data, analyzes the data, and makes the data available to one or more devices, including but not necessarily limited to a user device such as a smart device (109). Typically, the cloud storage system (119) is remote from the location where the tags (105) are installed.

The depicted server (121) may comprise the data aggregator, and may optionally include other and further software components to implement the systems and methods described herein, such as database management software, network server software, authentication systems, and other software components as would be understood by one of ordinary skill in the art. In an embodiment, computer server (121) and data storage system (119) may be combined into a single physical device or may be a plurality of devices, such as a cloud storage system or distributed computing network.

In the depicted embodiment, the smart device (109) receives (107) data from one or more tags (105) and transmits the received data, directly (117) or indirectly (123) and (125), to storage (119). Users may then retrieve and access the data about the electrical components (103) from storage (119). This may done using a client device or client application, such as but not limited to a web site, standalone software application, mobile device application, or other software, hardware, or combination thereof. The retrieved information may then be displayed, altered, removed, or otherwise manipulated. The particular content, architecture, and implementation of any such client will vary from embodiment and embodiment, and evolve over time with changing standards of user ergonomics, aesthetic preferences, and commonly accepted software engineering and design principles. Generally speaking, because the end-user is typically an electrician, client systems are carefully crafted to increase ease with which information is read, entered, used, and edited, in accordance with the task being attempted or performed.

It will be understood by one of ordinary skill in the art that the communications among devices described herein generally uses a telecommunications network. For sake of simplicity, this application will refer to connections with data storage (119) generically, and it will be understood that this means and implies both direct and indirect connections.

It is generally contemplated that tags exist in one of at least two states: passive or active. In the passive mode, data in storage (119) is generally accessible or otherwise made available to others by scanning one or more passive tags (105). The passive tags (105) have the advantage of drawing little or no power from the electric system. The association between such tags (105) and the components (103) is generally managed via the smart device (109) and server (121) side storage (109), and the tags may use energy from a querying device to respond to external requests.

In the depicted embodiment of FIG. 2, it is generally contemplated that passive tags (105) may respond (107) to a read request (107) from a smart device (109) with a unique identifier (201). The unique identifier (201) can be associated with data and/or metadata about the electrical system, and more particularly about the particular electrical component (103) with which the tag (105) is associated. This association is generally maintained in data storage (109) for later access and use. This data/metadata may include information such as, but not necessarily limited to: the voltage of the circuit; the current handling capacity of the circuit; unique identifier(s) associated with one or more parent tags; unique identifier(s) associated with one or more child tags; installer's information or data; maintenance history; location data (such as an approximate GPS coordinate); and, user-supplied information such as a label. In the depicted embodiments of FIGS. 1 and 2, such data is stored in storage (119) and can be accessed by an appropriate device, which may be a smart device (109).

In an embodiment, the smart device (109) may determine, calculate, or otherwise provide a unique identifier to a “blank” tag, or to replace or supplement a pre-populated manufacturer's identifier. This may be simpler and more cost effective, and allow users to manage and control the system, such as by developing tag identification schemas which can provide information efficiencies. By way of example and not limitation, all tags for mission-critical power systems in a hospital may have a special identifier prefix. This may also simplify tag purchasing.

While it may be possible to store some or all of the data/metadata in tag (105) memory, generally this data is stored instead in the storage system (119). This has several advantages. First, if the tag is lost, stolen, or fails, data stored in its memory may be irretrievably lost. Second, the security features of tag memory are generally limited. Third, the capacity of tag memory is limited and generally non-extendable. Fourth, centralizing the data in storage (119) improves data security, ease of access, and lowers maintenance costs, while also providing a single source of data for an entire system, making it simpler to back up, analyze, and access, especially remotely.

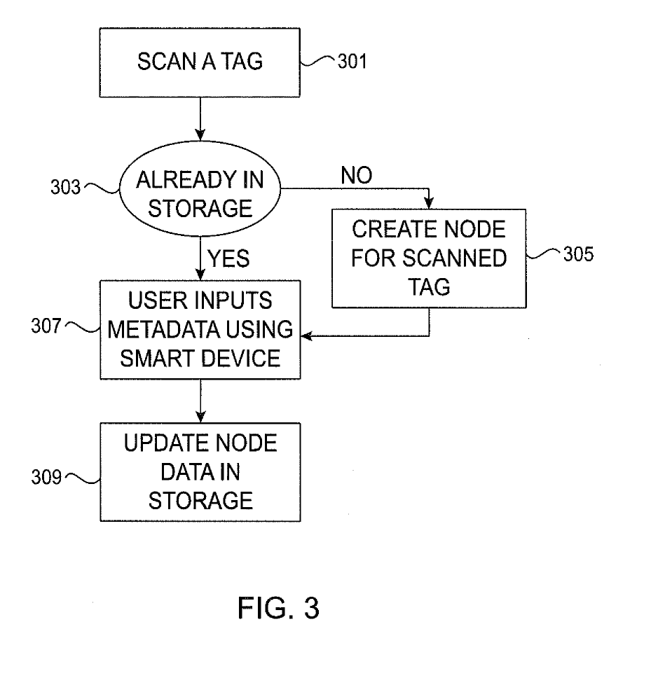

FIG. 3 depicts an embodiment of a method for creating and storing the data. Generally, a user scans (301) a tag using a smart device (105) as described herein, and the smart device determines, via communication with the data server (121) or data storage (119), whether a data set already exists for that tag's unique identifier (303). If not, a “blank” dataset is created for the identifier (305). Next, the user enters (307) metadata for the component, generally using the smart device (109), which is then transmitted (309) to storage (119) to fill in the “blank” dataset. One of ordinary skill in the art will appreciate that alternative methods are possible and the ordering of steps in this method is not the only possible technique. By way of example and not limitation, to save on network bandwidth, step (303) may be moved to just prior to step (309), such that the user scans (301) the tag to get the identifier, inputs the meta data (307) on the smart device (109), and then the identifier and entered data are transmitted (309) to the server (121) or storage (119). Then, it is determined whether an entry for that identifier exists (303) and, if not one is created (305) and populated with the received metadata. If one does exist, depending on business rules, it may be an error condition, or may be interpreted as a request to edit/update, and the existing entry is simply updated with the received information, to the extent the old data is inconsistent with the newly received data.

In the depicted embodiment of FIG. 3, tag (105) metadata is accessed by scanning (301) the tag (105) with a scanning device. For sake of simplicity, the scanning device will be assumed in this disclosure to also be a smart device (109), which may or may not be the same smart device (109) used to perform the initial inventory. One of ordinary skill in the art will appreciate that other devices may be functionally equivalent and can be substituted. The smart device (109) retrieves or determines the unique identifier for the tag (105) and queries storage (119) for metadata associated with the received unique identifier. Alternatively, the smart device (109) may query based on historical tag (105) scans, or for appropriate tag information from another device.

In the preferred embodiment of a passive tag system, the tags (105) communicate using radio-frequency identification protocols and standards, including near-field communication standards (“NFC”). Accordingly, the smart device (109) in such an embodiment comprises an NFC transmitter/receiver. The smart device (109) further includes application software for viewing/entering data (307) pertaining to each tag, and access to the storage system (119) for storing data collected or associated with the tag (105). As depicted in FIGS. 2 and 3, to use such a system, the user places a tag (105A) in an appropriate location within an electrical system, such as near to the electric component (103A) with which the tag identifier will be associated. Alternatively, the user may install components (103B) with such tags (105A), or functionally equivalent circuitry or elements, embedded in the component (103B). In an embodiment, one or more tags (105) may be added to an existing system. While it may be easier in some embodiments to use the tags (105) separately, new builds may make use of embedded tags (105B). For embedded tags (105B), the tag (105B) may comprise metadata stored in tag (105B) memory, which metadata is prepopulated with appropriate information about the component (103B). Such prepopulated data may reduce the burden of data entry, while increasing its reliability and accuracy.

Once the tags (105) are physically deployed in the system, they (105) are scanned (107) and linked together by the user using software. This may be done by manual linking of nodes or, preferably, through a scanning sequence for tag (105) linking A “node,” as used herein, generally means a logical dataset associated with a particular tag-component combination. By way of example and not limitation, a user may scan a first tag (105), choose a link mode (e.g., parent-child persistent), and then scan all child tags (105) which logically descend from the parent. This causes data relationships to be established in storage (119) linking the node associated with the parent tag (105) to the node (or nodes) associated with the child tags (105). As described elsewhere herein, this is generally performed by software on the smart device (109), which receives (107) data for each tag (105) and causes the appropriate data structures and relationships to be formed or updated in data storage (119), generally via a server.

Generally, when the user has finished scanning all direct children of a parent, the user discontinues link mode. This is generally done by manipulating a user interface of the smart device (109) to indicate as such. The user may then move on to the next set of relationships to scan. This could be, for example, an independent component with no parent/child relationship, another parent with one or more children, or a child tag may itself be a parent to a set of further child tags.

Data links between data nodes are generally formed by a server (121). The server (121) can recognize related nodes within linked structures such that independently scanned tags can be connected to existing link information (i.e., node data). The process effectively connects tags which have already been scanned and linked to newly scanned tags or other already-scanned tags. This allows for tag scanning at arbitrary times and in arbitrary order, because program logic is used to determine the final connection diagram based on tags which may be independently scanned.

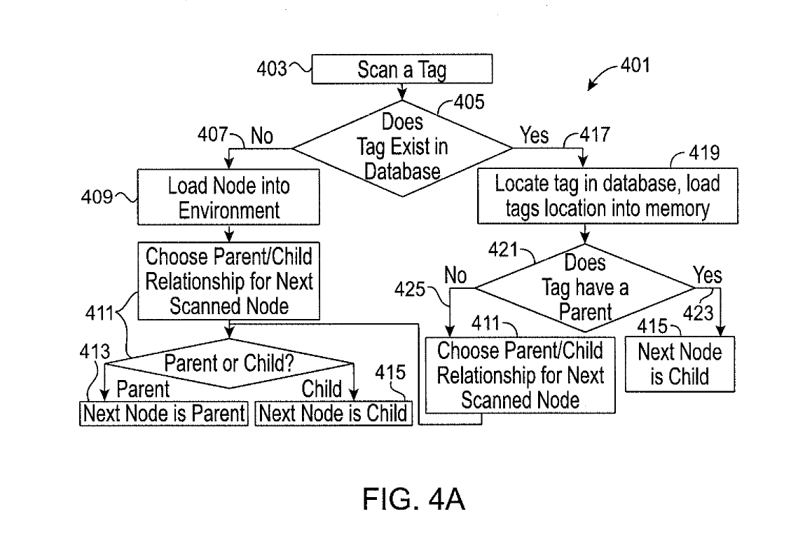

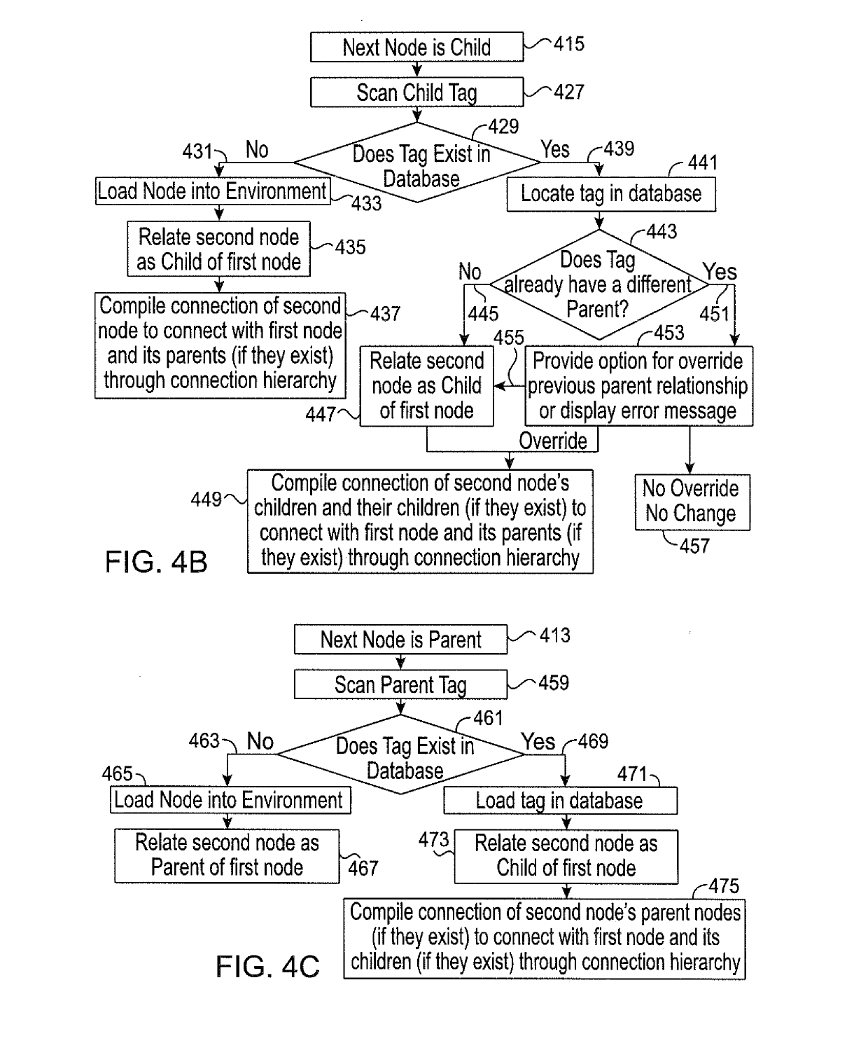

The following illustrative example is made with reference to FIGS. 4A and 4B and may provide further clarity. In the depicted embodiment of FIG. 4A, a first tag, associated with a first electrical component, is scanned (403). Again, scanning generally uses a handheld device as described elsewhere herein. A determination is made (405) as to whether a node for the first tag already exists in data storage (119). If such a first node does not (407) exist in data storage (119), a new first node is created (409) in the data storage (119) and the user may choose a parent/child relationship for the next scanned tag (411).

If parent is selected (413) then the method continues with FIG. 4C as described elsewhere herein. If child relationship is selected (415) the method continues with FIG. 4B, as described elsewhere herein. The selection of parent or child relationship describes the relationship between the first tag and a subsequent tag to be scanned. For example, if the first tag is associated with an electrical component which is a parent to the subsequent electrical component to be scanned, then parent relationship is generally selected. Conversely, if the electrical component is the child of the next component to be scanned, child relationship will generally be selected. As described elsewhere herein, these decisions and selections are usually provided by the user to the system through the user interface on the handheld user device (e.g., the user device (109)).

If the scanned tag does already have an associated node in the database (417), the previously-scanned tag data (i.e., node) is retrieved (419) from data storage (119), including the tag location in the electrical system. A determination is then made whether the retrieved node has a parent node (421). This determination is generally made by server software based upon the information in data storage (119). If the retrieved node does have a parent (423), the method continues with method step (415) as depicted in FIG. 4B. If the retrieved node (419) does not have a parent node (425), the user may choose parent or child relationship for the next scanned tag (411), as described elsewhere herein.

With reference to FIG. 4B, a second tag is scanned (427) and a determination is made (429) as to whether the second tag already has an associated node in data storage (119). If not (431) a second new node is created (433) in data storage (119), and such created second node is related (435) to the first node as a child of the first node in data storage (119). To the extent that the first node is already part of any existing node hierarchy (i.e., the first node already has data relationships in data storage (119) with a parent or child node), connecting the second node as a child of the first node effectively makes the second node a part of the first node's hierarchy (437).

If the second tag does already have an associated node in data storage (439), the node for that second tag is retrieved from the database (441) and a determination is made (443) as to whether the retrieved second node has a different parent node than the first node (443). If not (445), the retrieved second node is updated in data storage (119) to be a child of the first node (447). This effectively causes the children of the second node (if any) to become a part of the first node's hierarchy through the parent/child relationship between the first node and second node (449).

If the second node does have a different parent (451), an option may be provided to the user to override the prior relationship (453), or an error message may be displayed (453). If override is selected (455), the second node is updated in data storage (119) to reflect the newly-formed parent/child relationship (447) with the first node. Otherwise, no change need be made to the database (457).

In an alternative embodiment, a second node could be made a child of both the first node and the second node's previously existing parent node. In such an embodiment, the override or error step (453) may also change. By way of example and not limitation, a third option could be provided to maintain concurrent relationships between the second node and the first node, and the second node and its prior parent.

With reference to FIG. 4C, a second tag is scanned (459) and a determination is made (461) as to whether the second tag already has an associated node in data storage (119). If not (463), a second new node is created (465) in data storage (119), and related (467) to the first node as a parent of the first node. If the second tag does already have an associated node (469) in data storage (119), the node for that second tag is retrieved from the database (471) and updated to be a child node of the first node (473). This effectively causes the second node's parent node (if any) to connect to the first node and its children (if any) through the hierarchy (475).

The determination described with reference to FIGS. 4A, 4B, and 4C are generally performed by software executing on a server computer system. These determinations generally are based at least in part upon the contents of data storage (119). The server software generally operates autonomously with no direct input from the end user performing the scanning. In an alternative embodiment, the handheld device may itself contain software capable of making these determinations. For example, in an embodiment, the handheld device may directly query the data storage (119) and programmatically make the determinations described herein. However, this includes decision-making software on the handheld device, which can consume storage and processing power on the device. By contrast, server systems generally have enterprise level processing capabilities with faster access to data storage (119). Accordingly, while it is possible that the distribution of the program logic between the server and handheld device may differ from that generally described herein, it is preferred that the server shoulder the bulk of the load.

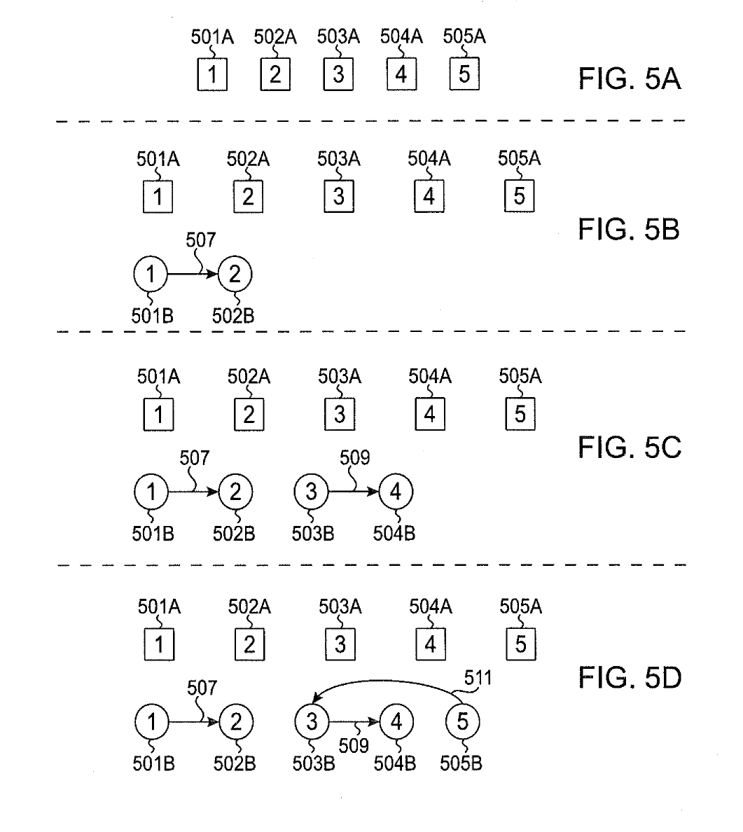

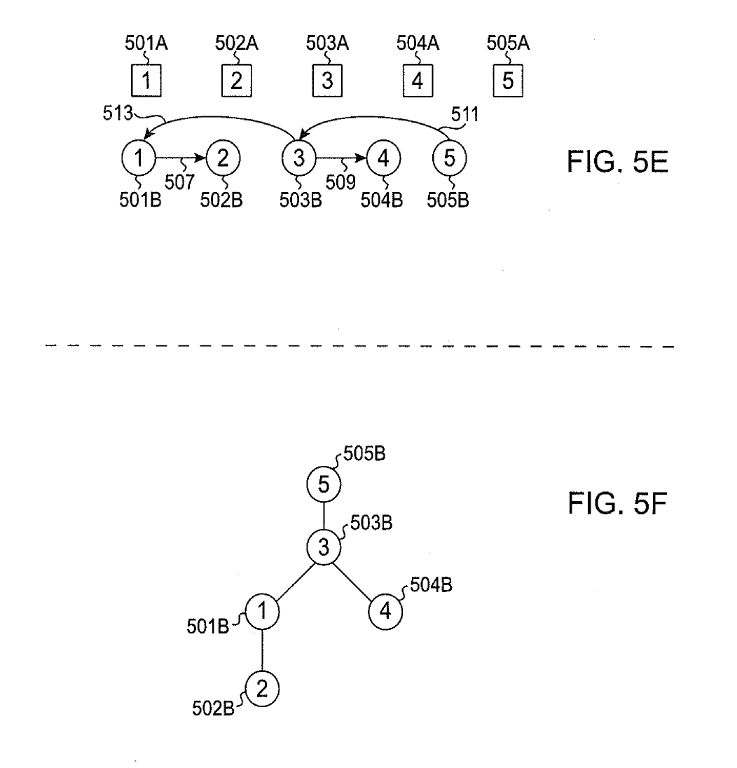

Using this method, a plurality of tags may be arranged into a hierarchy in data storage (119) regardless of the order in which the tags are scanned. For example, with reference to FIG. 5A, suppose an electrical system comprising five electrical components (501A, 502A, 503A, 504A, 505A) is to be diagrammed using the systems and method described herein.

As indicated in FIG. 5B, the first step may be to scan the first tag (501A) causing a first node (501B) for that tag to be created in data storage (119). When the second tag (502A) is also scanned, a second node (502B) for that tag (502A) is also created in data storage (119). The two nodes in memory (501B and 502B) are linked (507) with a parent/child relationship, regardless of which is scanned first.

As depicted in FIG. 5C, suppose a third tag (503A) is then scanned, causing a third node (503B) to be created in data storage (119). A fourth tag (504A) is then also scanned, causing a fourth node (504B) to also be created in memory (119). Because the user has indicated a parent/child relationship, a link (509) is established between nodes (503B) and (504B) indicating that node (503B) is a parent of the fourth node (504B).

Referencing FIG. 5D, a fifth tag (505A) is then scanned, and, since no associative node exists in data storage (119) for that tag (505A), a new fifth node (505B) is created in data storage (119). The fifth tag (505A) is scanned as a parent to the third tag (503A) and so the new fifth node (505B) is linked (511) to the third node (503B) as a parent. This effectively makes the fifth node (505B) a grandparent of the fourth node (504B), which is a child (509) of the third node (503B). It should be noted that, in this particular example, when the fifth node (505B) is linked to the third node (503B), the third node (503B) already exists in data storage (119) and thus a new node need not be created.

Finally, referencing FIG. 5E, the user determines that the third tag (503A) is a parent to the first tag (501A) (again, because the associated electrical components for the third (503A) and first (501A) tags, respectively, are in a parent/child relationship in the electrical system), the user scans tag (503B) and indicates that it should be a parent (513) to the first tag (501B). Again, it should be noted that because a node (503B) has already been created in the database for the third tag (503A) and a node (501B) has already been created in data storage (119) for the first tag (501A), no additional nodes need be created. Rather, the database entries for nodes (503B) and (501B) are simply updated to reflect the parent/child relationship (513).

Referencing FIG. 5F, this scanning technique, regardless of order, results in the hierarchy represented in FIG. 5F. In this hierarchy, the fifth node (505B) is the parent of the third node (503B), which is a parent to both the first node (501B) and the fourth node (504B), and the first node (501B) is a parent to the second node (502B). Although a particular scanning order was described in this illustrative example, the tags (501A) through (505A) can be scanned in any order, and at any time. Provided the user correctly identifies parent and child relationships, the program logic results in the hierarchical structure depicted in FIG. 5F. Thus, for example, if the operator forgets a node or omits a step, he or she may return and scan the missed electrical component (tag) and insert that component in the proper place in the hierarchy without having to rescan the entire system. This also makes it easier to extend or expand the electrical system to include new components or to include other previously scanned systems which were previously independent but are now connected to same electrical system.

This is faster than manual data entry and reduces errors. Connections between nodes are constructed in a structured, sequenced manner, and the smart device (109) and storage system (119) handle the complexities of establishing the data relationships, building an accurate data representation of the overall system, including relationships among components (103), regardless of the order in which the technician or user puts the information together. This is just one such mode for associating nodes. Other modes and methods may be used in an embodiment without departing from the spirit and scope of this disclosure.

In a preferred embodiment using passive tags (105), the particulars of how information is handled, processed, retrieved, stored, and distributed to the users is generally a function of application software on the smart device (109), and back-end or server software associated with the storage system (119). Generally, the user-facing application(s) on the smart device (109) include the user interface elements for entry of metadata for nodes, and may comprise preconfigured options. By way of example and not limitation, the application may prepopulate certain input fields with defaults to increase efficiency and consistency, and increase the speed at which links may be created between and among nodes. Such rapid creation of links between nodes requires that the methods for creating the individual links remains simple, letting the smart device (109) and storage components (119) handle the complexities of the overall link maps and the display of such information.

In an embodiment, active tags (105) may be used. In such a mode, user authentication would generally be required to access data in storage (119) collected by active tags (105). The active tags (105) generally include some at least minimal processing capacity, and a power source, such that they may actively acquire data from an electrical component (103) or wiring system. The active tags (105) generally actively read and/or record information and are capable of transmitting (107) said information to a smart device (109), whether or not the smart device has scanned the active tag (105). The active tags (105) may store metadata, such as by using an internal storage system or means, similar to the information stored in association with a passive tag (105); however, the active tags (105) may also collect information from the component (103), and/or its (103) environment, which information is then caused to be stored in the storage system (119) alongside metadata. The active tag (105) allows for the measurement of information such as the amount of current flowing through a wire. This information can be used to provide visualizations and other data representations to users. By way of example and not limitation, current amount can be used to provide users with a diagrammatic representation of power draws. This may be useful to a number of users, such as building owners or managers wishing to more accurately measure where power is flowing within their building.

The power source for an active tag (105) may be a battery, or may comprise a system, method, or means for drawing power from a component (103) of the power system, such as through the use of power siphoning technology such as wireless scavenging or pulling power from the alternating magnetic field if such a tag (105) is placed around a wire carrying alternating current. In a preferred embodiment, active tags (105) use Bluetooth Low Energy (“BLE”) combined transceiver and microprocessor devices, with attached battery, collecting information regarding the current flowing through the wire around which the active tag (105) is clipped. In the preferred case, the tag (105) would include a passive tag (105) element as well to enhance the linking in the metadata connection process.

Generally, the active tag (105) collects the current flow using standard techniques known in the art, such as a current clamp, where such data would be interpreted by the tag's (105) internal microprocessor or an equivalent system. In such an embodiment, the active tag (105) is generally non-invasive and, with an anticipated battery life of 3-5 years, will require infrequent replacement. In an alternative embodiment, the battery is omitted and replaced by a capacitor and energy harvesting system.

Where both an active and passive element are part of a single tag (105), the tag (105) may have a plurality of unique identifiers (one each for the active and passive tag elements), and may be reflected as such in storage (119), with one set of metadata being associated with two different nodes. Since the storage system (119) stores metadata in general, it can store active and passive elements within the same storage system (119).

In an embodiment, different current carrying capacity tags are created to measure varying levels of current flows through wires (e.g., 1-10 amps, 10-25 amps, 25-50 amps, etc.). However, it is contemplated that in such an embodiment, the data structures and collection methods remain generally similar to that described herein. Since the active tag (105) system is based upon BLE technology, it generally uses the smart device (109) to collect data from the tags (105) and transmit it to storage (119). This is because, typically, storage is remote from the tag installation, and the BLE technology cannot communicate directly with the storage system (119) due to the short transmission range. This means that when a smart device (109) is in range of an active tag (105), and the user requests a data collection event (or the smart device (109) is configured to automatically collect data when in range of active tags (105)), the active tags (105) transmit their data to the smart device (109), which then communicates with the storage system (119) to establish or update the appropriate nodes.

Once the metadata in storage (119) is generally complete for a given system, a wiring diagram can be programmatically generated ad hoc and on-demand. This in turn can provide users with data in real-time, or effectively real-time, on the overall structure and status of the system, including power consumption at various points. By way of example and not limitation, in a preferred embodiment of an active tag (105) system, the user may obtain a visualization or other representation of power flowing through a building, providing more granular insights into where power is being used in a system than is typically available through other means (e.g., by reading the power meter). The active tags (105) may have data collected individually by the smart device (109), or they (105) may employ a BLE mesh network to simplify the collection of data from the tags (105). In an alternative embodiment, a dedicated smart device (109) may be placed or established for consistent, real-time data-collection. This may also facilitate external requests for data collection, originating from the storage (119). For example, the storage system may track the timestamp of the last update for a tag and, where a smart device (109) is monitoring the system, request updates for those tags (105) having associated nodes in storage (119) which have not been updated for an amount of time in excess of a particular amount.

In the depicted embodiments, the storage system (119) may include all of the stored information about the system, and the links between elements. This depicted storage system (119) is generally an Internet-connected system, typically through a data server. The tagged information is stored in an efficient manner. In the case of the passive tag (105) data storage (119), each unique identifier has an associated node, in which the aforementioned metadata is stored, and the method of entering data into the smart device (109) allows for unique links between nodes to also be stored. Those links between data nodes show the connectivity of a system and how those nodes are linked together. Since the important information to the user is both the nodes and connections within a given system, information about any one system is generally segregated, segmented, or otherwise uniquely identifiable in the storage (119). By way of example and not limitation, the data for a particular system be associated with a unique identifier for the entire system. This reduces the likelihood that data for different systems becomes entangled, and improves information security.

In an embodiment, users can protect entered information, such as by requiring the user to enter authentication credentials, and thereby inhibiting unauthorized access. The user initially entering the data may choose the level of protection, be it entirely protected, read access only, or full editing permissions. Standard techniques known in the art for creating, managing, and applying access limitations through user identification and user groups may suffice for this purpose.

In certain embodiments, efficient electronic capture of wiring diagrams and maintenance history is allowed, along with efficient access of wiring diagrams. Also, in some embodiments, information from scanning tags is collected using either, or both, passive and/or active communication protocols. In some embodiments information flows from tags, through a smart device and into the cloud. And, in some embodiments, information of wiring diagrams is presented to electricians and homeowners.

Described herein, among other things, is a method for collecting, and storing electrical wiring diagram data comprising of the following elements: one or more electronic tags, comprising of: active or passive placed upon one or more wires, connectors, receptacles, switches, fuses, and/or circuit breakers; collecting data, both passively and actively collected from the tag including but not limited to a unique identifier for the association of metadata; entering metadata about that wire including, but not limited to voltage and current limits; a scanning/collection mechanism which allows the tag to be placed into such a diagram where the linkages between tags constitute an additional piece of valuable data; and a connected service to which the data is appended for later viewing.

Also described herein, among other things, is a method for retrieving and presenting electrical wiring diagram data comprising of the following steps: scanning/accessing the electronic tag in question with a smart device; using the queried information to present appropriately related sections of the diagram; showcasing appropriate entered metadata related to the tag.

Also described herein, among other things, is a method in which said data can be retrieved and presented for purposes such as showing the installer the current state of the installation. Also described herein, among other things, is a method in which said data can be edited for purposes such as updating the stored wiring diagram. Also described herein, among other things, is a method in which the tags comprise passive tags with unique identifiers which when scanned are associated with related nodes in the wiring diagram. Also described herein, among other things, is a method in which node association may automatically populate metadata across related nodes. Also described herein, among other things, is a method in which metadata comprise of the voltage and current carrying capacity of the segment from the wiring diagram.

Also described herein, among other things, is a method in which associated metadata allows for the depiction of the associated circuit breaker in the fuse box. Also described herein, among other things, is a method in which the tags comprise active tags with unique identifiers which collect data comprising of one or more of the following: current, voltage, temperature, humidity, carbon dioxide levels, carbon monoxide levels.

Also described herein, among other things, is a method in which such data is presented to a user on a smart device. Also described herein, among other things, is a method in which the data presentation shows the evolution of the collected data over time. Also described herein, among other things, is a method in which the data collected is the current flowing through the wire. Also described herein, among other things, is a method in which the data is aggregated in such a way to show the power flow through an electrical installation so as to provide insight to the manager of a building.

Also described herein, among other things, is a method in which a user scans a first tag, sets it as a base node, then scans attached nodes to create a set of branches for a wiring diagram. This process may be repeated at varying depths to create complex as-built wiring diagrams automatically without needing to draw the full system.

Also described herein, among other things, is a method in which the stored wiring diagram data can be accessed based on a previously scanned tag or information sent to the smart device wherein the smart device accessing the data need not directly scan the tag in question.

Also described herein, among other things, is a method in which the metadata includes a maintenance history.

Also described herein, among other things, is a passive electrical wiring tag system comprising of a remotely activated radio communication device such as NFC or RFID which can be scanned by smart device wherein said tags are applied to one or more wires, connectors, receptacles, switches, fuses, and/or circuit breakers.

Also described herein, among other things, is a passive electrical wiring tag system in which the passive tags are integrated into the electrical wire.

Also described herein, among other things, is a passive electrical wiring tag system in which the passive tags are integrated into a wire connector.

Also described herein, among other things, is an active electrical wiring system tag comprising of a microprocessor, memory, power source, wireless communication radio, and one or more of the following measurement devices: current sensor, temperature sensor, humidity sensor, voltage sensor, carbon dioxide sensor, carbon monoxide sensor, whereby such a tag collects data from the measurement device, processes it with the microprocessor, stores it in memory, and sends/receives information/commands with a smart device to provide the sensor information to the cloud.

While the invention has been disclosed in connection with certain preferred embodiments, this should not be taken as a limitation to all of the provided details. The intent of the invention is to use of known fiducial elements (tags) where connections between those elements represent data, and each fiducial element itself allows for the entering of additional data behind said fiducial element. Modifications and variations of the described embodiments may be made without departing from the spirit and scope of the invention, and other embodiments should be understood to be encompassed in the present disclosure as would be understood by those of ordinary skill in the art.

1. A method for collecting and storing electrical wiring diagram data comprising:
providing a plurality of electrical components installed in an electrical system;
for each electrical component in said plurality of electrical components:
associating with said each electrical component a tag having a memory containing a unique identifier for said tag;
receiving said unique identifier by a smart device;
entering, using said smart device, metadata describing said each electrical component;
transmitting, using said smart device, to a data server said unique identifier and at least some of said entered metadata;
storing in a non-volatile computer-readable storage medium a dataset for said each electrical component, said created dataset comprising an indication of said transmitted unique identifier, and said indication being associated in said created dataset with an indication of at least of some at least some of said transmitted entered metadata.

2. The method as claimed in claim 1, wherein for at least one of said each electrical components, said associating step comprises physically placing said tag proximate to said each electrical component.

3. The method as claimed in claim 1, wherein for at least one of said each electrical components, said associating step comprises placing said tag in physical contact with said each electrical component.

4. The method as claimed in claim 1, wherein for at least one of said each electrical components, said tag is physically integrated into said each electrical component.

5. The method as claimed in claim 1, further comprising:
for a first electrical component in said plurality of electrical components, said entering step further comprises indicating to said smart device that said first electrical component is a parent electrical component;
for a second electrical component in said plurality of electrical components, said entering step further comprises indicating to said smart device that said second electrical component is a child electrical component of said first electrical component;
associating, in said non-volatile computer-readable storage medium, said created dataset for said second electrical component with said created dataset for said first electrical component.

6. The method as claimed in claim 5 wherein said association of said second electrical component dataset with said first electrical component dataset is a parent/child relationship.

7. The method as claimed in claim 1, further comprising:
in response to a user request, for at least one electrical component in said plurality of electrical components, retrieving from said non-volatile computer-readable storage medium said created dataset for said at least one electrical component;
based upon said at least one retrieved datasets for said plurality of electrical components, generating a schematic diagram of said electrical system;
displaying said generated schematic diagram to a user.

8. The method as claimed in claim 1, further comprising:
for at least one electrical component in said plurality of electrical components, retrieving said identifier from tag associated with said at least one electrical component;
requesting said created dataset for said at least one electrical component, said requesting comprising transmitting said retrieved identifier for said associated tag;
receiving from said non-volatile computer-readable storage medium a copy of said created dataset for said at least one electrical component;
displaying a visualization of said received created dataset for said at least one electrical component.

9. The method as claimed in claim 8, wherein:
said displaying a visualization of said received created dataset for said at least one electrical component comprises displaying at least some of said indicated metadata associated in said dataset with said unique identifier;
editing said displayed at least some of said indicated metadata;
transmitting to said data server said unique identifier and said edited metadata;
updating in said non-volatile computer-readable storage medium said dataset for said at least one electrical component, said updating comprising altering said indication of at least of some of at least some of said transmitted entered metadata to conform to said transmitted edited metadata.

10. The method as claimed in claim 8, wherein said displayed visualization is displayed on said smart device.

11. The method as claimed in claim 8, wherein said displayed visualization is displayed on a second smart device.

12. The method as claimed in claim 8, wherein said displayed visualization includes a representation of the collected data over time.

13. The method as claimed in claim 1, wherein for at least one of said electrical components in said plurality of electrical components, said associated tag is a passive tag.

14. The method as claimed in claim 13, wherein said at least one passive tag is integrated into a wire component of said electrical system.

15. The method as claimed in claim 1, wherein for at least one of said electrical components in said plurality of electrical components, said associated tag is an active tag.

16. The method as claimed in claim 15, wherein:
collecting, by said at least one active tag, data indicative of a condition of said electrical system.

17. The method as claimed in claim 15, wherein said condition of said electrical system is selected from the group consisting of: current; voltage; temperature; humidity; carbon dioxide levels; and, carbon monoxide levels.

18. The method as claimed in claim 1, wherein said metadata includes data indicative of the voltage and current carrying capacity of a segment of the electrical system.

19. The method as claimed in claim 1, wherein at least one electrical component in said plurality of electrical components is selected from the group consisting of: wires; connectors; receptacles; switches; fuses; and, circuit breakers.
